(19) United States
(12) Patent Application Publication
(10) Pub. No.: US 2009/0040077 A1
(43) Pub. Date: Feb. 12, 2009

(54) UNIFIED USER INPUT DEVICE

(76) Inventors: Mark E. Repetto, Ozark, MO (US); Gregory M. Danaha, Ozark, MO (US); Richard L. Beard, Centennial, CO (US)

Correspondence Address: SHERIDAN ROSS PC, 1560 BROADWAY, SUITE 1200, DENVER, CO, 80202, US

(21) Appl. No.: 12/235,433

(22) Filed: Sep. 22, 2008

Related U.S. Application Data
(63) Continuation of application No. 10/940,503, filed on Sep. 13, 2004.

(51) Int. Cl. H03K 17/94; H04N 7/18

(52) U.S. Cl. 341/22; 348/160; 348/E07.085

(57) ABSTRACT

A unified user input device is provided. The input device may include keys normally provided as part of a general purpose alphanumeric computer keyboard. In addition, a positional controller is provided. Both the conventional alphanumeric keys and the positional controller are associated with the same device platform. Additionally, special function keys may also be provided in association with the positional controller. Signals encoding the selection of an alphanumeric key, a control input, or a special function key are communicated to an interconnected computer using a common, conventional keyboard connection, and a common signaling protocol.

### CROSS REFERENCE TO RELATED APPLICATIONS

This application is a continuation application of co-pending U.S. application Ser. No. 10/940,503, filed Sep. 13, 2004, entitled: “UNIFIED USER INPUT DEVICE”, which is incorporated herein in its entirety by this reference.

### FIELD OF THE INVENTION

The present invention relates to a unified user input device that includes selectable alphanumeric keys and a positional controller. A selection of an alphanumeric key or input to the positional controller is encoded and provided to a receiving device using a defined signaling protocol.

### BACKGROUND OF THE INVENTION

Security systems that provide for the centralized control and/or surveillance of facilities typically include a number of subsystems. For example, the different sub systems may include an access control, intercom communication, video surveillance, digital video recording, alarm, building management (e.g. HVAC) and lighting control systems. As a result, the control of such sub systems from a central facility can be complex and inefficient.

In order to facilitate the operation of multiple sub systems in connection with a facility or groups of related facilities, integrated security systems have been developed, In an integrated security system, many operations can be conducted through specialized integration software that presents a single graphical user interface. Such operations may include opening doors, responding to alarms, placing and answering intercom calls, and selecting video cameras to display or record. However, controlling the movement of selected video cameras is difficult. In particular, if control is to be achieved through a personal computer, an operator must use a standard mouse or keyboard as the input devices to control the cameras. Alternatively, controlling camera movement requires the use of a hardware based controller, such as a joystick, trackball or touchpad, that is specific to the video surveillance subsystem or digital video recording subsystem. These hardware controllers reside on separate control panels, and do not form part of the standard personal computer keyboard. Even with “integrated” security systems, at least a separate hardware control panel is required if it is desired to control a camera other than by the standard input devices of a personal computer. As between control of a camera using a mouse or keyboard keys and control using a positional input device such as a joystick, the positional input device is generally preferable.

Because positional controllers such as joysticks have utilized hardware-based controllers, a control station for an integrated security system might have multiple security subsystem hardware specific input devices for controlling video surveillance subsystems as well as others for digital video recording systems. In addition to these specially provided input devices, the standard keyboard is still required for operation of the computer on which the specialized integration software is operating. Furthermore, each of the positional control input devices typically require the use of a serial port and a specialized device driver. Accordingly, the integration and control of video surveillance subsystems in connection with an integrated security system has been complex for users to implement and operate. In addition, the need for multiple input devices can create a cluttered and inefficient control facility.

### SUMMARY OF THE INVENTION

The present invention is directed to solving these and other problems and disadvantages of the prior art. In accordance with embodiments of the present invention, a unified user input device is provided. The unified user input device includes alphanumeric keys, comprising a conventional/standard computer keyboard layout, that are associated with a single device platform. In addition, the unified user input device includes a positional controller, also associated with the first device platform. In accordance with still other embodiments of the present invention, the unified user input device may incorporate a pointing device, such as a touchpad. A unified user input device in accordance with embodiments of the present invention therefore presents to the user a universal device that can be used for operating all sub systems of an integrated security system and conventional computer applications.

In accordance with embodiments of the present invention, the single device platform is interconnected to a general-purpose computer using a conventional keyboard signal line attached to a conventional keyboard port on the general-purpose computer. In addition, the signals provided by the unified user input device to the general-purpose computer may be encoded according to a conventional protocol. For example, in accordance with embodiments of the present invention, selection of an alphanumeric key may result in the transmission of a printable character from the unified user input device to the general purpose computer, while the selection of a specialized input button or of a control input at the positional controller may result in the provision of a non-printable character to the general purpose computer.

The physical layout of a unified user input device in accordance with embodiments of the present invention includes a conventional alphanumeric computer keyboard with the addition of a joystick, trackball, and/or touchpad, and several application specific keys, for controlling functions that are typical of video surveillance systems and/or digital video recording systems. Accordingly, a unified user input device in accordance with embodiments of the present invention does not require a user to move between different, physically separate input devices in order to affect control of an integrated security system. In addition, a unified user input device in accordance with embodiments of the present invention utilizes a single, conventional keyboard interconnect, and therefore does not require the routing of additional cables from a positional controller to the computer.

In general, the standard keyboard keys are used to control the integration software, while the positional controller is used to control the movement of video surveillance cameras. Application specific keys may be assigned to specialized functions associated with controlling the video surveillance subsystems, or other subsystems. For example, the application specific keys, in conjunction with the numeric keypad of the standard keyboard, can be used to directly call cameras using camera numbers from the video surveillance subsystems and digital video recording subsystems, as well as place calls using station numbers from the intercom subsystems. Accordingly, a typical example of the use of a unified user input device in accordance with embodiments of the present invention includes selection of a video surveillance camera to view and control by using a pointing device such as a mouse to place a cursor on an icon displayed as part of a floor plan type map. This selects the camera to be displayed and controlled. The user may then move the positional controller such as a joystick or may use application specific keys to control the operation of the selected video surveillance camera or digital video recorder.

In further aspects, embodiments of the present invention provide integration software that allows for the control of multiple video surveillance subsystems and other subsystems from various manufacturers using the unified user input device. For example, inputs made using keys included as part of the standard alphanumeric keyboard section of the unified user input device may be routed to a currently selected integrated security system application or other selected application, while inputs entered using the positional controller section of the unified user input device may be routed to a video or other subsystem.

Additional features and advantages of the present invention will become more readily apparent from the following description, particularly when taken together with the accompanying drawings.

### BRIEF DESCRIPTION OF THE DRAWINGS

FIG. 1 is a schematic depiction of an integrated security system such as may be operated in connection with a unified user input device in accordance with embodiments of the present invention;

FIG. 2 is a screen shot of an integrated security system application such as may be used in connection with a unified user input device in accordance with embodiments of the present invention;

FIG. 3 depicts a unified user input device in accordance with embodiments of the present invention in plan view;

FIG. 4 is a schematic depiction of components of a unified user input device in accordance with embodiments of the present invention;

FIG. 5 is a block diagram depicting software that may be used in association with a unified user input device in accordance with embodiments of the present invention; and

FIG. 6 is a flowchart depicting aspects of the operation of a user input device in accordance with embodiments of the present invention.

### DETAILED DESCRIPTION

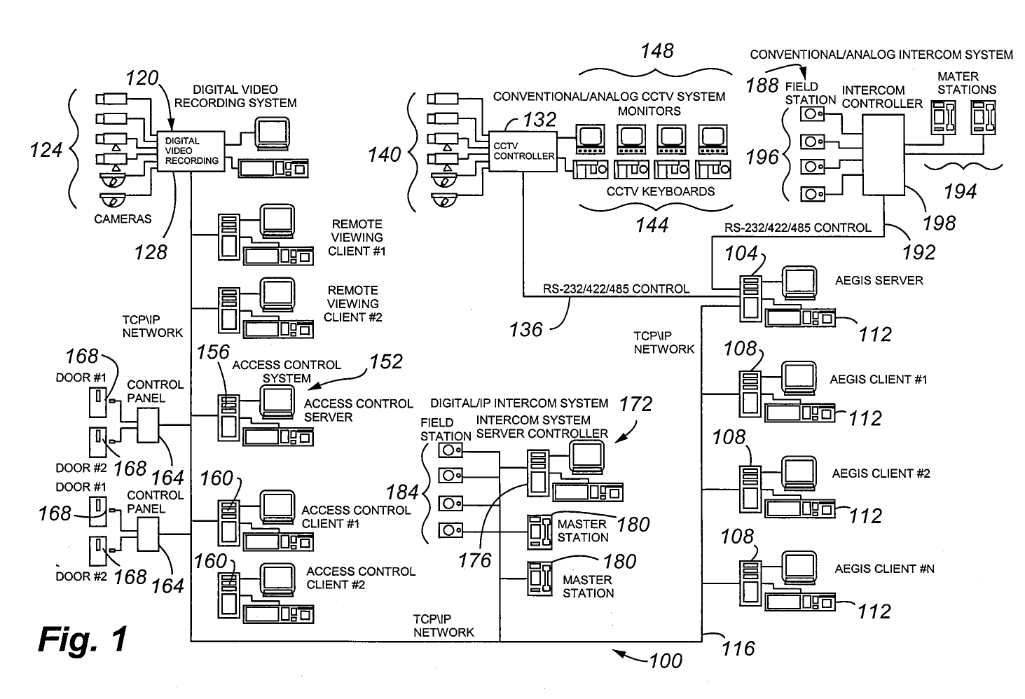

With reference now to FIG. 1, an integrated security system 100, such as may be operated in connection with a unified user input device in accordance with embodiments of the present invention, is depicted in schematic form. The system 100 may include an integrated security system server 104. In addition, one or more integrated security system client computers 108 may be provided. Furthermore, the integrated security system server 104 or clients 108 may each be associated with a unified user input device 112 in accordance with embodiments of the present invention.

The integrated security system server 104 and clients 108 are generally interconnected to a communication network 116. The communication network 116 is, in accordance with embodiments of the present invention, a transmission control protocol/Internet protocol (TCP/IP) network. Furthermore, the communication network 116 may be local. In addition, the communication network 116 may interconnect facilities that are physically remote from one another. Accordingly, the communication network 116 may comprise a corporate intranet and/or the public Internet.

Through the communication network 116, the integrated security system server 104 and clients 108 may be operably connected to a variety of devices and subsystems. For example, the system 100 may include a digital video recording subsystem 120 that is associated with one or more video cameras 124. In addition, the digital video recording subsystem 120 may be associated with a recording device 128. As a further example, the system 100 may include a conventional analog closed circuit television system 132. The CCTV system 132 may be interconnected to the integrated security system server 104 through a dedicated control channel 136. The CCTV system 132 may include one or more cameras 140, recording devices 144 and monitors 148.

An access control system 152 may also be included in the integrated security system 100. The access control system 152 may include an access control server 156 and access control clients 160. Alternatively, the functions of the access control server 156 and/or clients 160 may be integrated into the integrated security system server 104 and/or clients 108. In general, an access control system 152 may include one or more control panels 164 for distributing control signals to and receiving signals from electronic locks, identification devices, and/or key devices 168, which may be associated with a door or other barrier.

The integrated security system 100 may also include various intercom systems. For example, a digital intercom system 172 may be interconnected to the integrated security system server 104 and clients 108 by the communication network 116. The intercom system 172 may include a controller 176, one or more master stations 180, and one or more remote stations 184. As a further example, a conventional analog intercom system 188 may be interconnected to, for example, the integrated security system server 104 though a dedicated control channel 192. The analog intercom system 108 may include a number of master stations 194 interconnected to a number of remote stations 196 through an intercom controller 198.

The integrated security system 100 may additional include other systems and subsystems not depicting in FIG. 1. For instance, an integrated security system 100 may include building control subsystems, such as heating ventilation and air conditioning (HVAC) subsystems. In addition, the integrated security system 100 may be associated with one or more facilities. In addition, an integrated security system 100 may operate in connection with one or more entities. For example, a security provider may operate an integrated security system 100 in connection with a number of enterprises.

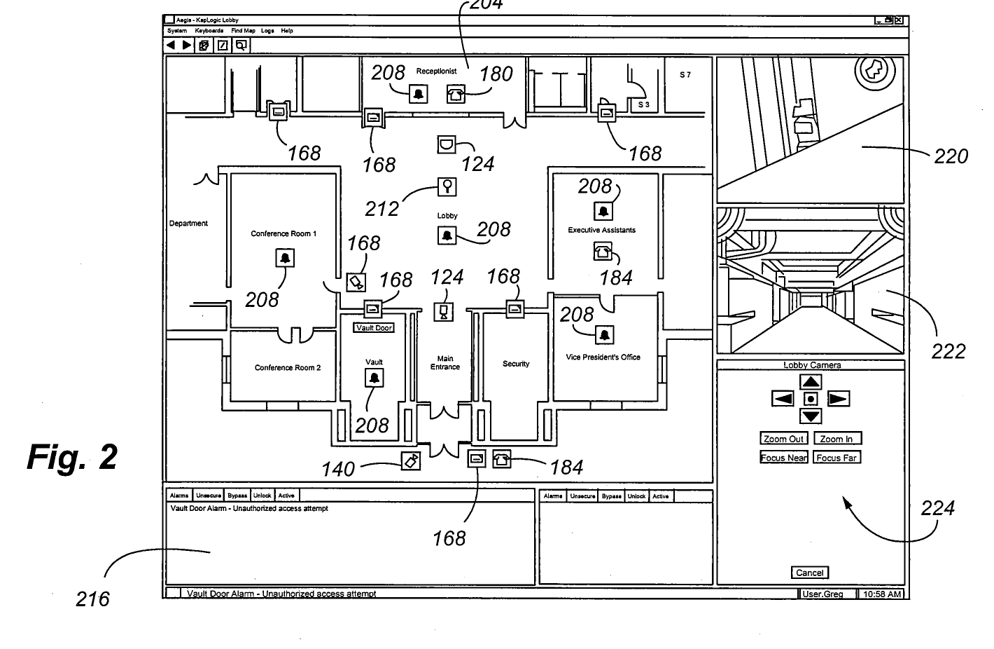

With reference now to FIG. 2, a screen shot illustrating an example of output that may be provided by an integrated security application running on or in association with an integrated security system server 104 or client 108 is depicted. In this example view, a floor plan type map 204 of all or a portion of a monitored facility is shown. In addition, each device, such as a digital video camera 124, CCTV video camera 140, access device 168, alarm point 208, intercom station 180, 184, or light 208 is represented by an icon placed on the map 204. As can be appreciated by one of skill in the art from the description provided herein, an alarm point 208 may comprise an automatic and/or manual alarm activation point. As can also be appreciated by one of skill in the art from the description provided herein, a light 212 or other aspects of the operation of a facility may be controlled through the integrated security system application in cooperation with a building control or other subsystem.

In addition to the map 204, various information about a selected device may be displayed in a sub-window 216. For example, information regarding current or recent alarm codes, the status of access devices 168 or other information regarding a selected device or a device that the system determines requires attention from security personnel, can be displayed in the sub-window 216.

Video output windows 220, 222 may also be provided. In general, the video output windows 220, 222 may display a live feed from a video camera 124, 140. A video output window 220, 222 may also be used to play back recorded video information. Although two video output windows 220, 222 are shown, it should be appreciated that any number of video output windows may be provided.

In connection with the control of a video camera 124, 140, control icons 224 may be provided. In general, the control icons 224 may be used to control a currently selected video camera 124, 140. Furthermore, the output from a video camera 124, 140 that is to be controlled may be displayed in the video output window 222 directly above the input buttons 224.

An operator may select individual devices displayed on the map 204 using a pointing device, such as a conventional mouse, interconnected to the integrated security system server 104 or client 108 being used by the operator. Similarly, the control buttons 224 may be selected using such a pointing device. However, as can be appreciated by one of skill in the art, using a pointing device such as a mouse to select buttons displayed as part of a graphical user interface for cameral control moves the operator one step away from precise control of a camera. The repeated clicking action of a mouse does not provide an operator with the same “feel” in terms of controlling the camera as does a joystick.

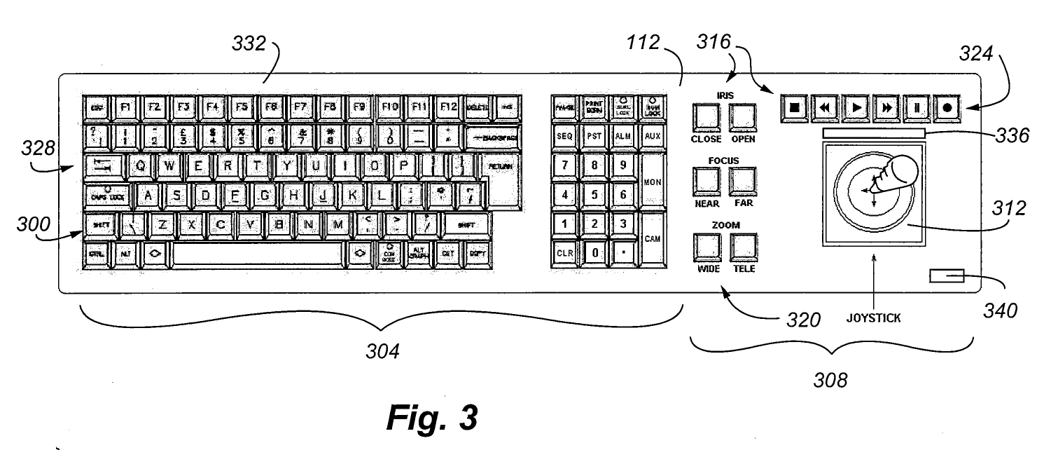

With reference now to FIG. 3, a unified user input device 112 in accordance with embodiments of the present invention is illustrated in plan view. In general, the unified user input device 112 includes a plurality of keys 300 comprising a conventional or standard alphanumeric computer keyboard section 304. As can be appreciated by one of skill in the art, various function keys can be provided, such as function, shift, delete, backspace, and other keys may also be included in the conventional alphanumeric keyboard section 304. In addition, the unified user input device 112 comprises a positional control section 308. The positional control section 308 includes a positional control device 312 for receiving positional control inputs from a user. Examples of a positional control device 312 include a joystick, trackball or touchpad. The joystick can be either one of a conventional configuration, that is, one that is full-sized for grasping by the hand wherein the height of the joystick extends far enough above the input device so that the palm and fingers of the hand may comfortably grip the joystick. Alternatively, the joystick can be smaller where only a limited number of fingers can comfortably grasp the joystick. In addition, the positional control section 308 of the unified user input device 112 may include a plurality of input buttons 316 that allow the user to control specific functions associated with a selected device. Examples of such functions may include those associated with the operation of a camera 124, 140. Accordingly, buttons 320 for the iris or aperture opening, focus, zoom, included viewing angle, pan, or tilt of a camera 124, 140 may be provided. Other input buttons 316 may be adapted for control of other devices, such as digital or video recorders associated with a digital 120 or CCTV 132 system. The recorder buttons 324 may include stop, rewind, play, fast forward, pause and record buttons. In general, input buttons 316 may include buttons for any function that it is desirable to access directly through an associated button 316.

The unified user input device 112 generally provides a single platform 328 that contains the keys of a conventional or alphanumeric keyboard portion 304, and the positional control device 312 and buttons 316 of the positional controller section 308. The platform 328 may include a top surface 332 defining an area within which the conventional keyboard section 304 and positional controller section 308 are contained. The top surface 332 of the unified user input device 112 may be substantially planar.

The unified user input device 112 may also include an electronic readout or display 336. This display 336 may be positioned above or near the positional controller 312, and may be used to provide status and mode information related to the unified user input device 112 to the user. The unified user input device 112 may also include a reader or scanner 340 for receiving bio-metric data related to a user, for example in connection with authenticating the identity of the user.

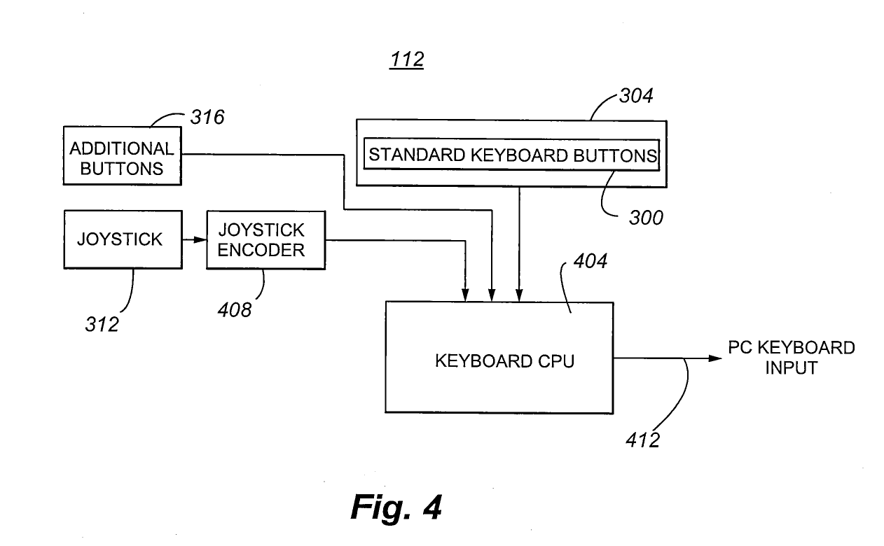

With reference now to FIG. 4, components of a unified user input device 112 are illustrated in block diagram form. In particular, the unified user input device 112 includes a keyboard central processing using (CPU) 404 that receives signals derived from various of the individual keys or input devices associated with the unified user input device 112. For example, the selection of a key 300 included within the conventional keyboard section 304 results in an identification signal being provided to the keyboard CPU 404. The keyboard CPU 404 may, in response to receiving an indication that a particular key 300 within the conventional keyboard section 304 has been depressed, generate a signal encoding that key according to a first signaling protocol. Likewise, when a button 316 is selected, the keyboard CPU 404 uses information received regarding the identity of the selected button 316 to generate a signal encoding the selected function for provision to the receiving device. In accordance with embodiments of the present invention, the selection of a standard keyboard button 304 or an additional button 316 is associated with an identified position in a keyboard matrix.

The joystick or other positional control device 312 may be an optical or other position encoding device that sends data pulses to an encoder circuit 408. The encoder circuit 408 activates data inputs on the keyboard CPU 404, emulating activation by typical computer type keys. In general, information regarding the direction and amplitude of control inputs made using the joystick 312 may be encoded. Other joystick 312 movements that may be encoded include twisting or rotating the joystick 312 and depressing the joystick 312.

The keyboard CPU 404 generally encodes signals representing the selection of a particular standard key 304 associated with a letter, number or other printable character as that printable character, using a first signaling protocol. The selection of an additional button 316, or a control input provided through the positional controller 312 is encoded as an unprintable character, again using the first signaling protocol. As used herein, an unprintable character refers to a character that is not normally represented in graphical form by a signaling protocol. However, as can be appreciated by one of skill in the art, a graphic corresponding to an encoded selection or input may be generated according to extended character sets and/or in response to the selection of a special print command. Accordingly, it can be appreciated that a unified user input device 112 in accordance with embodiments of the present invention can make use of characters that are not normally printed, but that are encoded in order to provide control signals to an interconnected general purpose computer.

The keyboard CPU 404 provides an output 412 to an interconnected general-purpose computer, which may include an integrated security system server 104 or client 108. More particularly, the output 412 is carried by a conventional keyboard connector. Examples of the signaling channel include a PS/2 or USB channel. Furthermore, it should be appreciated that the signaling protocol used to encode printable and non-printable characters may comprise ASCII code or a variant thereof. Therefore, operable connection of a positional controller 312 and specialized input buttons 316 to a receiving device does not require the use of a communications channel that is separate from and/or in addition to a conventional keyboard connector.

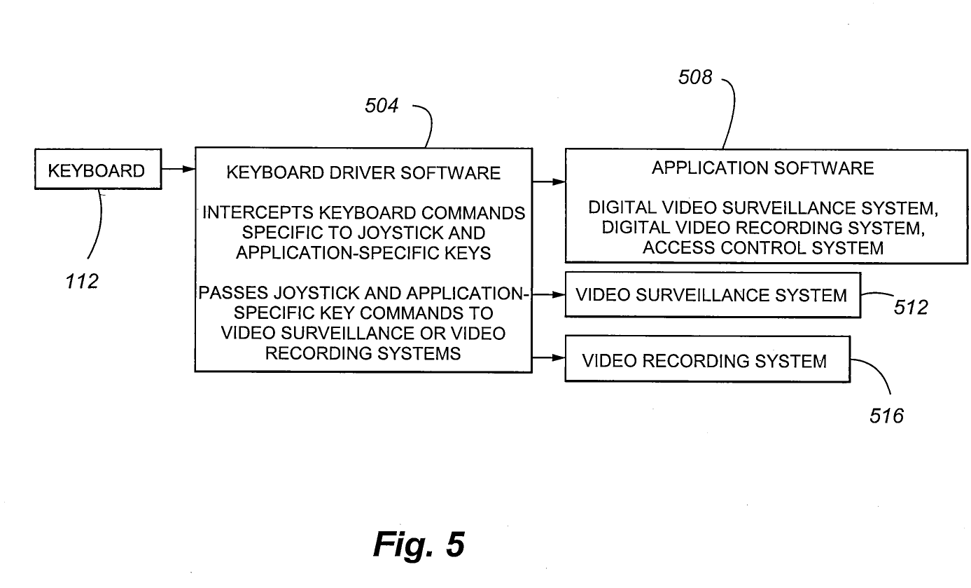

With reference now to FIG. 5, the relationship between a unified user interface device 112 and software running on a general-purpose computer, such as an integrated security system server 104 or client 108, is illustrated. In particular, the output from the unified user interface 112 is provided to a keyboard driver software application 504. Keyboard commands representing the selection of keys included as part of the conventional keyboard 304 portion of the unified user interface device 112 are provided to application software 508 conventionally. Accordingly, such commands are provided to the active or selected application software 508.

Signals encoding commands associated with operation of the positional controller 312 or associated buttons 316 are intercepted by the keyboard driver software 504. Such commands may be passed to an activated video surveillance system 512 or video recording system 516. Furthermore, the keyboard driver software 504 may, if required, perform translation of the encoded signals, for example where the video surveillance system 512 or video recording system 516 is otherwise adapted to receive signals from a dedicated hardware device that is, for example, interconnected to the computer by a peripheral data input. In accordance with embodiments of the present invention, such translation facilities may be provided as specialized drivers or plug-ins to the keyboard driver software 504.

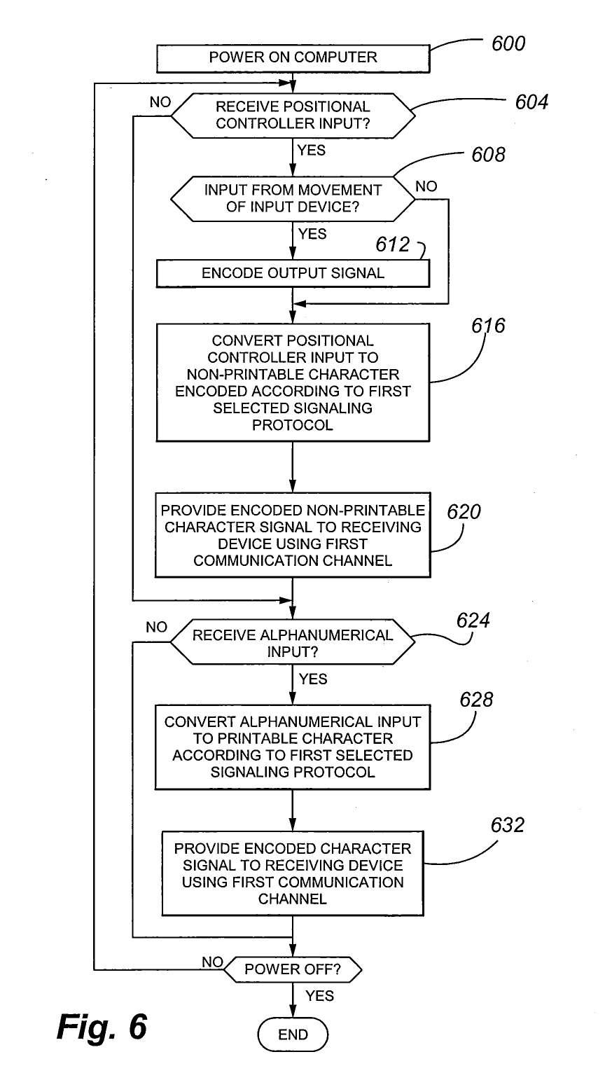

With reference now to FIG. 6, aspects of the operation of a unified user input device 112 in accordance with embodiments of the present invention are illustrated. Initially, at step 600, the computer (e.g. server 104 or client 108) is powered on. At step 604, a determination is made as to whether a positional controller input has been received. As can be appreciated by one of skill in the art from the description provided herein, a positional controller input may generally include a control input from a user to the device 112 using the positional controller 312. In addition, positional controller input may include the selection of a button 316 provided as part of the positional controller section 308 of the unified user input device 112.

If a positional controller input has been received, a determination is made as to whether that input was entered through movement of the positional input device 312 (step 608). If the input is from the positional input device 312, the output signal from that device 312 is encoded, for example in the encoder 408 (step 612). After encoding the output from the positional input device 312, or if the input is from one of the buttons 316 provided as part of the positional controller input section 308, the positional controller input is converted to a non-printable character encoded according to a first selective signaling protocol (step 616). In accordance with embodiments of the present invention, the first selected signaling protocol may comprise the ASCII protocol.

After encoding the received input, the encoded non-printable character is provided to the receiving device using a first communication channel (step 620). In particular, the standard keyboard connection between the unified user input device 112 and the associated general-purpose computer is used to signal the selected input to that general-purpose computer.

After transmission of a non-printable character encoding a selected input to the general purpose computer, or after determining that a positionable controller input has not been received, a determination may be made as to whether a conventional alphanumeric input has been received, for example through a key included in the conventional keyboard section 304 of the unified user input device 112 (step 624). If an alphanumeric input has been received, that alphanumeric input is converted to a printable character according to the first selected signaling protocol (step 628). The encoded character is then provided to the receiving device using the first communication channel. Accordingly, it can be appreciated that both positional control inputs and conventional alphanumeric character selections are provided to a general purpose computer using the same or conventional keyboard connection. In addition, both the positional controller input and conventional alphanumeric key selections are communicated to the general-purpose computer using the same signaling protocol.

At step 636, a determination is made as to whether the system has been powered off. If the system has not been powered off, that process may return to step 604. If the system has been powered off, the process ends.

As can be appreciated by one of skill in the art from the description provided herein, the present invention provides a unified user input device that integrates a conventional keyboard with a positional controller in a single device platform. Further, output signals generated in response to user input entered through the conventional keyboard section and in response to user input entered through the positional controller section are encoded in accordance with the same signaling protocol. Therefore, a unified user input device in accordance with embodiments of the present invention can be interconnected to a general purpose computer using a single, conventional keyboard communication channel or interconnect. Furthermore, although examples of use of a unified user input device as disclosed herein are given in connection with integrated security systems, including video surveillance subsystems, the present invention is not so limited. For instance, embodiments of the present invention may be used in connection with any application in which the use of a positional control device 312 is convenient or desired.

The foregoing discussion of the invention has been presented for purposes of illustration and description. Further, the description is not intended to limit the invention to the form disclosed herein. Consequently, variations and modifications commensurate with the above teachings, within the skill or knowledge of the relevant art, are within the scope of the present invention. The embodiments described hereinabove are further intended to explain the best mode presently known of practicing the invention and to enable others skilled in the art to utilize the invention in such or in other embodiments and with the various modifications required by their particular application or use of the invention. It is intended that the appended claims be construed to include alternative embodiments to the extent permitted by the prior art.

What is claimed is:

1. A system for controlling operation of a multiple component system, comprising:
a device platform;
(i) an alphanumeric keyboard including a first plurality of keys incorporated in said device platform, wherein selection of a key included in said first plurality of keys provides a signal encoding a printable character in accordance with a first signaling protocol; and
(ii) a positional controller also incorporated in said device platform, wherein said positional controller provides a first output signal;
a first processor, wherein said first output signal provided by said positional controller is translated into at least a first non-printable character in accordance with said first signaling protocol;
a single common communication channel interconnected to said device platform, wherein said signal encoding a printable character in accordance with a first signaling protocol and said signal encoding at least a first non-printable character in accordance with said first signaling protocol are both simultaneously carried by said communication channel to a receiving device, wherein said signal encoding a printable character in accordance with a first signaling protocol is carried to a first system application and wherein said signal encoding at least a first non-printable character in accordance with said first signaling protocol is carried to a seconds system application; and
a positional controller encoder, wherein said encoder translates a position of said positional controller into said first output signal.

2. The system of claim 1, wherein said first processor additionally provides said signal encoding a printable character in accordance with said first signaling protocol in response to said selection of a key included in said first plurality of keys.

3. The system of claim 1, further comprising:
a second processor, wherein said second processor operates to provide said signal encoding a printable character in accordance with said first signaling protocol to said communication channel.

4. The system of claim 1, wherein said positional controller comprises at least one of a joystick, a touch pad, a mouse, a trackball, and a button.

5. The system of claim 1, wherein said positional controller includes a joystick, said joystick extending from a surface of said device platform, wherein an end of said joystick is at least one inch from said surface of said device platform.

6. The system of claim 5, wherein said positional controller additionally includes a plurality of input buttons.

7. The system of claim 6, wherein selection of a button included in said plurality of input buttons provides a signal encoding a non-printable character in accordance with said first signaling protocol.

8. The system of claim 1, wherein said receiving device comprises a personal computer.

9. The system of claim 8, wherein said personal computer is running application software comprising an integrated video surveillance subsystem.

10. The system of claim 8, wherein said personal computer is running application software comprising video surveillance camera control software.

11. The system of claim 1, wherein said operation of said positional controller comprises moving a joystick provided by said position controller, wherein said moving a joystick produces said first output signal, wherein said first control signal is translated to said at least a first non-printable character.

12. The device of claim 1, wherein said communication channel comprises one of a PS/2 and a USB cable.

13. The system of claim 1, wherein said first signaling protocol includes ASCII encoding.

14. The system of claim 1, wherein said device platform includes a first area defined by a first perimeter, and wherein said alphanumeric keyboard and said positional controller are located within said first area.

15. A method for controlling components of a surveillance system, comprising:
receiving from a user input device a selection of an alphanumeric character;
producing a signal encoding said selected alphanumeric character as a printable character according to a first communication protocol;
receiving from said user input device a control input from a positional controller associated with said user input device;
producing a signal encoding said received control input as a non-printable character according to said first communication protocol;
outputting said signal encoding said selected alphanumeric character and said signal encoding said received control input as a non-printable character on a single common communication channel for transmission to first and second applications respectively, wherein said first and second applications are associated with a selected device and wherein said first application is provided for controlling operational characteristics of said selected device and wherein said second application is provided for controlling positional characteristics of said selected device;
wherein said user input device includes an integrated device platform having a plurality of alphanumeric keys for selecting the alphanumeric character and a positional controller for creating the control input;
encoding at least a first aspect of said control input; and
converting said encoded at least a first aspect of said control input a non-printable character according to said first communication protocol.

16. The method of claim 15, wherein said at least a first aspect of said control input includes one of a stroke amplitude and a stroke direction.

17. The method of claim 15, wherein said encoding at least a first aspect of said control input is performed by a first processor and wherein said producing a signal encoding said selected alphanumeric character is performed by a second processor.

18. The method of claim 15, wherein said producing a signal encoding said selected alphanumeric character as a printable character according to a first communication protocol comprises producing a signal encoding said selected alphanumeric character using an ASCII code corresponding to said printable character.

19. The method of claim 15, wherein said producing a signal encoding said received control input as a non-printable character according to said first communication protocol comprises producing a signal encoding said control input using an ASCII code corresponding to a non-printable character.

20. An integrated keyboard device, comprising:
means for receiving selected alphanumeric inputs associated with a first keyboard platform;
means for first encoding said selected alphanumeric inputs;
means for outputting said first encoded selected alphanumeric inputs;
means for receiving selected positional control inputs associated with said first keyboard platform;
means for second encoding said selected positional control inputs;
means for outputting said second encoded selected positional control inputs on a single common communication channel;
means for simultaneously directing said first encoded inputs to a first application and said second encoded inputs to a second application, wherein the first and second applications are active at the same time and wherein means for simultaneously directing is further operable to intercept and separate said second encoded inputs from said first encoded inputs.

21. A system for controlling operation of a multiple component system, comprising:
a device platform having;
(i) an alphanumeric keyboard incorporated in said device platform, said alphanumeric keyboard including alphanumeric keys for each letter of the alphabet (A-Z), a plurality of function keys designated as at least keys F1-F10, a plurality of numeric keys designated as keys 1-9;
(ii) a positional controller incorporated in said device platform and spaced from said plurality of alphabetical, numeric, and function keys, said positional controller being in the form of a joystick, said joystick for controlling one or more cameras within said system, said joystick extending above said device platform enabling a user to grip said joystick with the palm of a user's hand;
(iii) a plurality of camera control keys for controlling various camera functions including at least a plurality of camera control keys for controlling focus and zoom of said camera;
said alphabetical keys and said numeric keys providing a signal encoding for production of printable characters in accordance with a first signaling protocol;
said positional controller providing another output signal;
a first processor incorporated within said device platform, wherein said another output signal provided by said positional controller is translated into at least a first non-printable character in accordance with said first signaling protocol;
a single common communication channel interconnected to said device platform for carrying said signal encoding a printable character in said another signal encoding at least a first non-printable character to a receiving device, said receiving device being in the form of a computing device having at least a second processor, and data storage means for storing data.
